(19) United States
(12) Patent Application Publication
(10) Pub. No.: US 2024/0243146 A1
(43) Pub. Date: Jul. 18, 2024

(54) IMAGING DEVICE AND ELECTRONIC EQUIPMENT

(71) Applicant: SONY SEMICONDUCTOR SOLUTIONS CORPORATION, KANAGAWA (JP)

(72) Inventor: SAKAYA TAKAI, KANAGAWA (JP)

(21) Appl. No.: 18/579,950

(22) PCT Filed: Jul. 27, 2022
(86) PCT No.: PCT/JP2022/028924

§ 371 Date: Jan. 17, 2024

(30) Foreign Application Priority Data
Aug. 6, 2021 (JP) 2021-130155

(51) Int. Cl. H01L 27/146

(52) U.S. Cl. CPC H01L 27/14623; H01L 27/14621

(57) ABSTRACT

[Object]

To enhance the utilization efficiency of incident light and prevent color mixture.

[Solving Means]

An imaging device includes a photoelectric conversion region including a photoelectric conversion portion for each of pixels, a dispersion region that is arranged on a side nearer to a light incidence face than the photoelectric conversion region and that causes incident light to be dispersed according to a wavelength, and a light shielding member arranged along a boundary of pixels which light dispersed in an angle different from a chief ray angle in the dispersion region enters.

### TECHNICAL FIELD

The present disclosure relates to an imaging device and electronic equipment.

### BACKGROUND ART

There has been proposed a color imaging element in which spectroscopic elements including a microstructure are arranged on the light incidence face side of a photoelectric conversion element array (refer to PTL 1).

In the color imaging element of PTL 1, since incident light is dispersed for each wavelength by the spectroscopic elements and photoelectric conversion is performed by the photoelectric conversion element array, even if a color filter is not used, photoelectric conversion can be performed separately for each color, and the utilization efficiency of light in the photoelectric conversion can be enhanced.

### CITATION LIST

### Patent Literature

### [PTL 1]

Japanese Patent Laid-Open No. 2019-184986

### SUMMARY

### Technical Problem

However, in the color imaging element of PTL 1, there is the possibility that, since the dispersed light propagates in an oblique direction, the light may come into an adjacent pixel and may cause color mixture. In PTL 1, a countermeasure against color mixture is not taken.

Therefore, it is an object of the present disclosure to provide an imaging device and electronic equipment that can enhance the utilization efficiency of incident light and can prevent color mixture.

### Solution to Problem

In order to solve the problem described above, according to the present disclosure, there is provided an imaging device including a photoelectric conversion region including a photoelectric conversion portion for each of pixels, a dispersion region that is arranged on a side nearer to a light incidence face than the photoelectric conversion region and that causes incident light to be dispersed according to a wavelength, and a light shielding member arranged along a boundary of pixels which light dispersed in an angle different from a chief ray angle in the dispersion region enters.

The light shielding member may cause light transmitted through a corresponding pixel to be reflected or absorbed.

The light shielding member may extend in a depthwise direction of the photoelectric conversion region along the boundary of the pixels.

The light shielding member may include a conductive material that causes incident light to be reflected or absorbed.

The light shielding member may include a material having a refractive index lower than that of the photoelectric conversion region.

The light shielding member may have a cavity portion filled with air.

The dispersion region may cause the light dispersed in a direction according to the wavelength of the incident light to enter a pixel of a corresponding color in the photoelectric conversion region.

A plurality of pixels may be arranged in order for each color along one direction in the photoelectric conversion region, the dispersion region may cause the light dispersed in a direction according to the wavelength of the incident light to enter at least some of the plurality of pixels arranged in the one direction in the photoelectric conversion region, and the light shielding member may be arranged along a boundary of pixels which the light dispersed in the dispersion region enters.

The light shielding member may be arranged only on a boundary of some of the plurality of pixels arranged in the one direction in the photoelectric conversion region.

The light shielding member may be arranged on the boundary of all of the plurality of pixels arranged in the one direction in the photoelectric conversion region.

The imaging device may include a color filter region that is arranged between the photoelectric conversion region and the dispersion region and that includes color filters corresponding to the pixels.

The light shielding member may be arranged at at least one of a pixel boundary portion in the color filter region or a pixel boundary portion in the photoelectric conversion region.

The light shielding member may be arranged to extend from the pixel boundary portion in the photoelectric conversion region to the pixel boundary portion in the color filter region.

The light shielding member may include a first light shielding portion arranged along a pixel boundary in the color filter region, and a second light shielding portion that is arranged along a pixel boundary in the photoelectric conversion region and that includes a material different from that of the first light shielding portion.

The first light shielding portion may include a material that causes the incident light to be reflected, and the second light shielding portion may include a conductive material that causes the incident light to be reflected or absorbed.

At least one of the first light shielding portion or the second light shielding portion may have a cavity portion filled with air.

An interval of a pixel boundary portion in the color filter region at a location at which the first light shielding portion is arranged may be greater than an interval of a pixel boundary portion of pixels which a chief ray enters.

The dispersion region may include a first microstructure that causes the incident light to be dispersed in one direction according to the wavelength and that allows the incident light to advance straightforwardly in a direction intersecting the one direction, and the light shielding member may be arranged along a boundary of at least some of the pixels in the one direction.

The first microstructure may transmit therethrough light in a specific wavelength band and causes light in any wavelength band other than the specific wavelength band to be dispersed in the one direction, and the light shielding member may be arranged along a boundary of pixels corresponding to the wavelength bands other than the specific wavelength band in the one direction.

The imaging device may include a plurality of the first microstructures arranged along a direction intersecting the one direction.

The imaging device may include a second microstructure that is arranged along a face of the photoelectric conversion portion on a side opposite to the light incidence face and that diffuses light transmitted through the photoelectric conversion portion.

The second microstructure may be provided for each of all of the photoelectric conversion portions or is provided for some of the photoelectric conversion portions that perform photoelectric conversion for light having a specific wavelength.

According to the present disclosure, there is provided electronic equipment including an imaging device that outputs a pixel signal obtained by imaging, and a signal processing section that performs signal processing for the pixel signal. The imaging device includes a photoelectric conversion region including a photoelectric conversion portion for each of pixels, a dispersion region that is arranged on a side nearer to a light incidence face than the photoelectric conversion region and that causes incident light to be dispersed according to a wavelength, and a light shielding member arranged along a boundary of pixels which light dispersed in an angle different from a chief ray angle in the dispersion region enters.

### BRIEF DESCRIPTION OF DRAWINGS

FIG. 1 is a block diagram depicting a general configuration of an imaging device according to an embodiment of the present disclosure.

FIG. 2 is a view illustrating a principle of a microstructure.

FIG. 3 is a view depicting a particular example of a dispersion region according to the present disclosure.

FIG. 4 is a top plan view of an essential part of an imaging device according to a first embodiment.

FIG. 5A is a cross-sectional view taken along line A-A of FIG. 4.

FIG. 5B is a cross-sectional view taken along line B-B of FIG. 4.

FIG. 6 is a circuit diagram of each pixel arranged in a photoelectric conversion region.

FIG. 7 is a top plan view of an essential part of an imaging device according to a second embodiment.

FIG. 8A is a cross-sectional view taken along line A-A of FIG. 7.

FIG. 8B is a cross-sectional view taken along line B-B of FIG. 7.

FIG. 9A is a top plan view of an essential part of an imaging device according to a third embodiment.

FIG. 9B is a top plan view of an essential part of an imaging device according to a modification of FIG. 9A.

FIG. 10 is a cross-sectional view of an imaging device according to a fourth embodiment.

FIG. 11 is a cross-sectional view of an imaging device according to a first modification of FIG. 10.

FIG. 12 is a cross-sectional view of an imaging device according to a second modification of FIG. 10.

FIG. 13 is a cross-sectional view of an imaging device according to a third modification of FIG. 10.

FIG. 14 is a cross-sectional view of an imaging device according to a fourth modification of FIG. 10.

FIG. 15 is a cross-sectional view of an imaging device according to a fifth modification of FIG. 10.

FIG. 16 is a view depicting an example in which light enters from a direction normal to a light incidence face.

FIG. 17 is a view depicting an example in which light enters from a direction inclined with respect to the direction normal to the light incidence face.

FIG. 18 is a cross-sectional view of an imaging device according to a sixth embodiment.

FIG. 19 is a cross-sectional view of an imaging device according to a first modification of FIG. 18.

FIG. 20 is a cross-sectional view of an imaging device according to a seventh embodiment.

FIG. 21 is a cross-sectional view of an imaging device according to an eighth embodiment.

FIG. 22 is a cross-sectional view of an imaging device according to a modification of FIG. 21.

FIG. 23 is a block diagram depicting an example of schematic configuration of a vehicle control system.

FIG. 24 is a diagram of assistance in explaining an example of installation positions of an outside-vehicle information detecting section and an imaging section.

### DESCRIPTION OF EMBODIMENTS

In the following, embodiments of an imaging device and electronic equipment are described with reference to the drawings. Although the following description is given focusing on main constituent portions of an imaging device and electronic equipment, the imaging device and the electronic equipment may possibly have constituent portions and functions that are not depicted or described. The following description does not exclude such constituent portions or functions that are not depicted or described.

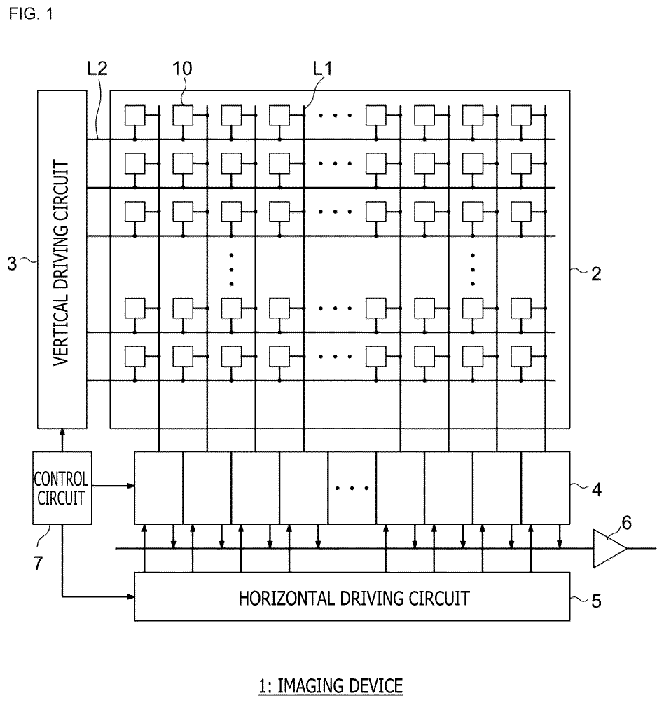

FIG. 1 is a block diagram depicting a general configuration of an imaging device 1 according to an embodiment of the present disclosure. Although it is supposed that the imaging device 1 of FIG. 1 images incident light in a visible light band, the imaging device 1 may perform imaging of IR light.

The imaging device 1 of FIG. 1 includes a pixel array section 2, a vertical driving circuit 3, a column signal processing circuit 4, a horizontal driving circuit 5, an outputting circuit 6, and a control circuit 7.

The pixel array section 2 includes a plurality of pixels 10 arranged in a row direction and a column direction, a plurality of signal lines L1 extending in the column direction, and a plurality of row selection lines L2 extending in the row direction. Though not depicted in FIG. 1, each pixel 10 has a photoelectric conversion portion and a readout circuit that reads out a pixel signal according to charge obtained by photoelectric conversion to a signal line L1. The pixel array section 2 is a laminated body in which a photoelectric conversion region in which photoelectric conversion portions are arranged in a two-dimensional direction and a readout circuit region in which readout circuits are arranged in the two-dimensional direction are laminated.

The vertical driving circuit 3 drives the plurality of row selection lines L2. In particular, the vertical driving circuit 3 line-sequentially supplies a driving signal to the plurality of row selection lines L2 to line-sequentially select the row selection lines L2.

To the column signal processing circuit 4, the plurality of signal lines L1 extending in the column direction are connected. The column signal processing circuit 4 performs analog-to-digital (AD) conversion of a plurality of pixel signals supplied thereto through the plurality of signal lines L1. More specifically, the column signal processing circuit 4 compares a pixel signal on each signal line L1 with a reference signal and generates a digital pixel signal on the basis of a period of time until signal levels of the pixel signal and the reference signal become coincident with each other. The column signal processing circuit 4 sequentially generates a digital pixel signal (P-phase signal) of a reset level of a floating diffusion layer in a pixel and a digital pixel signal (D-phase signal) of a pixel signal level to perform correlated double sampling (CDS).

The horizontal driving circuit 5 controls the timing at which an output signal of the column signal processing circuit 4 is transferred to the outputting circuit 6.

The control circuit 7 controls the vertical driving circuit 3, the column signal processing circuit 4, and the horizontal driving circuit 5. The control circuit 7 generates a reference signal that is used by the column signal processing circuit 4 to perform AD conversion.

The imaging device 1 in FIG. 1 can be configured by laminating a first board on which the pixel array section 2 and so forth are arranged and a second board on which the vertical driving circuit 3, the column signal processing circuit 4, the horizontal driving circuit 5, the outputting circuit 6, the control circuit 7, and so forth are arranged, with use of Cu—Cu connection, bumps, vias, or the like.

A photodiode PD of each pixel in the pixel array section 2 is arranged in the photoelectric conversion region. Though not depicted in FIG. 1, the imaging device 1 according to the present embodiment includes a dispersion region arranged on the side nearer to the light incidence face than the photoelectric conversion region. The dispersion region causes incident light to be dispersed according to its wavelength. The dispersion region has a microstructure, for example, for each pixel.

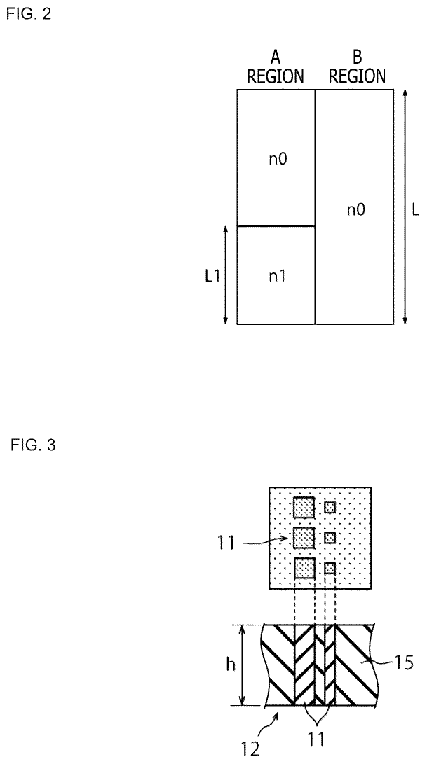

FIG. 2 is a view illustrating a principle of a microstructure and indicates an example in which an A region and a B region that individually transmit light therethrough are arranged adjacent to each other. The A region and the B region have a length L in a propagation direction of light. The B region has a refractive index n0. In contrast, the A region has a refractive index n0 at a part (L−L1) thereof and has another refractive index n1 at the remaining part L1 thereof.

An optical path length dA of the A region and an optical path length DB of the B region in FIG. 2 are represented by the following expressions (1) and (2), respectively.

$$dA = n 0 \times ( L - L 1 ) + n 1 \times L 1 … \qquad ( 1 )$$

$$dB = n 0 \times L … \qquad ( 2 )$$

Therefore, an optical path length difference Δd between the A region and the B region is represented by the following expression (3).

$$Δ d = dB - dA = L 1 ( n 0 - n 1 ) … \qquad ( 3 )$$

Meanwhile, a phase difference φ between the A region and the B region is represented by the following expression (4).

$$φ = 2 π L 1 ( n 0 - n 1 ) / λ … \qquad ( 4 )$$

As indicated by the expression (4), rays of light propagating in the A region and the B region are different in optical path length depending on a difference in refractive index between the A region and the B region, and are also different in propagation direction depending on the difference in refractive index. The difference in propagation direction depends on the wavelengths of the rays of light. Hence, by selecting a material having a refractive index suitable for the wavelength band of incident light in advance, the dispersion region can be used as a color filter.

The dispersion region according to the present embodiment is also called color splitter (CFS: Color Filter Splitter). Since the color splitter can bend incident light to an angle according to the wavelength thereof, it can achieve a function similar to that of a color filter. Since a color filter transmits only light in a specific wavelength band therethrough, light in wavelength bands other than the specific wavelength band is discarded wastefully. However, since the color splitter described above can bend light at angles different among different wavelength bands, the utilization efficiency of light is enhanced.

If the color splitter is used alone, there is the possibility that the bent light may come into an adjacent pixel, and a desired dispersion characteristic cannot be obtained. To cope with this problem, it is also possible to use a color filter in combination with the color splitter. In this case, in order to prevent color mixture, the thickness of the color filter may be made smaller than that of an ordinary color filter for the imaging device 1.

FIG. 3 is a view depicting a particular example of a dispersion region 12 according to the present disclosure. An upper part of FIG. 3 is a top plan view, and a lower part of FIG. 3 is a cross sectional view.

As depicted in the top plan view of FIG. 3, the dispersion region 12 according to the present disclosure has a plurality of microstructures 11 arranged in one direction along a pixel column of a specific color (wavelength). The microstructures 11 are divided into a plurality of types that are different in width from each other. Although, in FIG. 3, two types of microstructures 11 having widths different from each other are depicted, three or more types of microstructures 11 having widths different from one another may be provided.

Each microstructure 11 is a columnar body having a length h in the propagation direction of light as indicated in the cross sectional view of FIG. 3. It is to be noted that, although an example in which the microstructure 11 has a cubic shape is depicted in FIG. 3, the microstructure 11 may have a cylindrical shape. The microstructure 11 is surrounded by a light transmission region 15 of, for example, SiO₂ or the like. Here, the term “transmission” signifies that incident light in a wavelength band of an imaging target is transmitted. The refractive index n1 of the microstructure 11 is made higher than the refractive index n0 of the light transmission region 15. The material of the microstructure 11 is, for example, SiN.

Light entering the microstructure 11 propagates in a state in which it is confined in the inside of the microstructure 11 due to the refractive index difference between the microstructure 11 and the light transmission region 15. Therefore, the microstructure 11 functions as an optical waveguide for the incident light. As indicated by the expression (4) above, light propagating in the inside of the microstructure 11 causes a phase difference (phase delay amount) φ according to the refractive index difference between the microstructure 11 and the light transmission region 15. The phase delay amount φ takes a value depending on the wavelength λ of light.

Further, by providing a plurality of types of microstructures 11 having widths different from each other as depicted in FIG. 3, it is possible to provide a phase delay distribution that differs for each wavelength band, to the light having propagated in the inside of the microstructure 11, and change an optical wavefront. Since the propagation direction of light is determined by the optical wavefront, light having propagated in the microstructure 11 can be dispersed in directions different from each other depending on the wavelength.

In the present embodiment, it is assumed that incident light includes rays of light in visible light wavelength bands of red, green, and blue and, when the incident light propagates in the inside of the microstructure 11, the ray of light in the wavelength band of green advances straightforwardly without being bent while the ray of light in the wavelength band of red and the ray of light in the wavelength band of blue are bent in directions opposite to each other.

In the following, particular examples of the imaging device 1 that includes the dispersion region 12 having such an optical characteristic as depicted in FIG. 3 are described.

### First Embodiment

The imaging device 1 according to the first embodiment includes a block configuration similar, for example, to that of FIG. 1 and is characterized in the layer configuration of the pixel array section 2. The pixel array section 2 according to the first embodiment includes a photoelectric conversion region 13 and a dispersion region 12 arranged on the light incidence face side of the photoelectric conversion region 13.

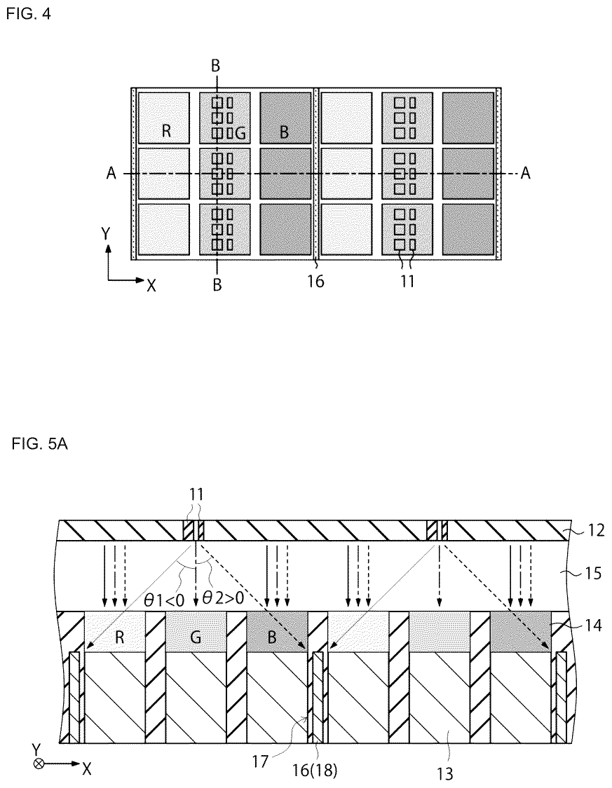

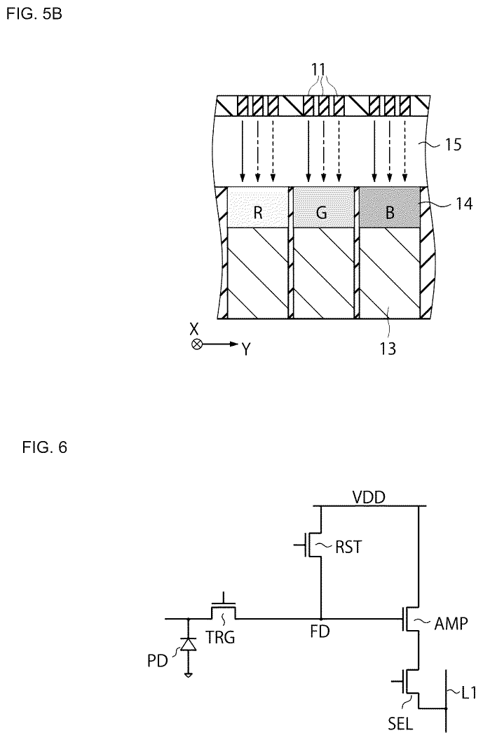

FIG. 4 is a top plan view of an essential part of the imaging device 1 according to the first embodiment, FIG. 5A is a cross sectional view taken along line A-A of FIG. 4, and FIG. 5B is a cross sectional view taken along line B-B of FIG. 4. The imaging device 1 according to the first embodiment includes the photoelectric conversion region 13, a color filter region 14, a light transmission region 15, and the dispersion region 12. Among them, the color filter region 14 is not an essential component and may be omitted in some cases.

The top plan view of FIG. 4 is a view obtained when the imaging device 1 is viewed in plan from above the dispersion region 12, and an upper face of the dispersion region 12 is a light incidence face. It is to be noted that an on-chip lens array may be arranged on the upper face of the dispersion region 12 as hereinafter described. In a case where an on-chip lens array is arranged, the surface of the on-chip lens array becomes a light incidence face.

As depicted in FIG. 4, red pixels R, green pixels G, and blue pixels B are arranged in order in an X direction, and pixels of the same color are arranged in a lined-up relation in a Y direction.

The dispersion region 12 has two kinds of microstructures 11 having widths different from each other, as in FIG. 3. It is to be noted that the size and shape of the microstructures 11 are freely determined. The microstructures 11 in the dispersion region 12 are arranged above the green pixels G. Although, in FIG. 4, three sets of the two types of microstructures 11 are arranged above one green pixel G, this arrangement is one example, and the type and number of the microstructures 11 are freely determined. Since a plurality of green pixels G are arranged in the same column in the Y direction, a plurality of microstructures 11 are arranged above the plurality of green pixels G arranged in the Y direction.

The microstructure 11 has an optical characteristic of dispersing incident light in a specific direction. In particular, while the microstructure 11 disperses incident light in the X direction according to the wavelength as depicted in FIG. 5A, it does not disperse the incident light in the Y direction and allows the incident light to advance straightforwardly.

In the example of FIG. 5A, the microstructure 11 refracts light in the wavelength band of red included in the incident light in a negative direction with respect to a chief ray direction of the incident light, refracts light in the wavelength band of blue in a positive direction with respect to the chief ray direction, and allows light in the wavelength band of green to advance straightforwardly in the direction of the incident light.

Therefore, light coming straightforwardly from above and light refracted by the microstructure 11 enter a red color filter. Similarly, light coming straightforwardly from above and light refracted by the microstructure 11 enter a blue color filter. Light transmitted through the microstructure 11 and coming straightforwardly enters a green color filter.

While a red color filter in a case where the dispersion region 12 does not exist transmits therethrough only light in the red wavelength band from within light entering from above, in the present embodiment, the red color filter transmits therethrough not only light entering from above the red color filter but also light that is in the red wavelength band and that has been refracted by the microstructure 11 above the green color filter. Similarly, while a blue color filter in a case where the dispersion region 12 does not exist transmits therethrough only light in the blue wavelength band from within light entering from above, in the present embodiment, the blue color filter transmits therethrough not only light entering from above the blue color filter but also light that is in the blue wavelength band and that has been refracted by the microstructure 11 above the green color filter.

FIG. 6 is a circuit diagram of each pixel arranged in the photoelectric conversion region 13. Both pixels above which the microstructure 11 is arranged and pixels above which the microstructure 11 is not arranged include the same circuit.

As depicted in FIG. 6, each pixel includes a photodiode PD, a transfer transistor TRG, a floating diffusion layer (FD: Floating Diffusion), a reset transistor RST, an amplification transistor AMP, and a selection transistor SEL.

The reset transistor RST is turned on once before exposure is started by the photodiode PD, and discharges accumulated charge in the floating diffusion layer FD to a power supply voltage node VDD. Thereafter, a P-phase signal according to a reset level of the floating diffusion layer FD is sent to a signal line L1 through the amplification transistor AMP and the selection transistor SEL. Thereafter, the transfer transistor TRG is turned on, and the charge photoelectrically converted by the photodiode PD is accumulated into the floating diffusion layer FD. Then, a D-phase signal according to the charge accumulated in the floating diffusion layer FD is sent to a signal line through the amplification transistor AMP and the selection transistor SEL.

In this manner, in the imaging device 1 according to the present embodiment, the amount of light that is transmitted through the color filter region 14 can be increased, and the utilization efficiency of light can be enhanced, in comparison with an alternative case in which the dispersion region 12 does not exist.

In the present embodiment, a light shielding member 16 is arranged along a pixel boundary between the red pixels R and the blue pixels B. The light shielding member 16 is provided so as to prevent the light having been dispersed by the microstructure 11 and advancing obliquely from entering an adjacent pixel.

More precisely, the light shielding member 16 is arranged along a boundary of pixels which the light dispersed at an angle different from the chief ray angle in the dispersion region 12 enters. In the case of FIG. 5A, the chief ray angle direction is a direction in which light advances straightforwardly without being refracted by the microstructure 11 and enters the green color filter. The direction of one of rays of light dispersed at angles different from the chief ray direction is a direction in which the ray enters the red color filter, and the direction of the other ray of light is a direction in which the ray enters the blue color filter. In FIG. 5A, the angle of the direction in which light is refracted by the microstructure 11 and advances toward the red color filter is θ1, and the angle of the direction in which light is refracted by the microstructure 11 and advances toward the blue color filter is θ2. The angles θ1 and θ2 are angles with respect to the chief ray direction, and in FIG. 5A, the angle θ1 is a negative angle, and the angle θ2 is a positive angle.

The light shielding member 16 is provided on the boundary of pixels at which light dispersed by the microstructure 11 and advancing in the direction of the angle θ1 arrives and the boundary of pixels at which light dispersed by the microstructure 11 and advancing in the direction of the angle θ2 arrives.

The light shielding member 16 is provided in the inside of a trench 17 that is formed in a depthwise direction of the photoelectric conversion region 13 along the boundary between pixels. The trench 17 may be formed from the light incidence face side or may be formed from the side opposite to the light incidence face. The light shielding member 16 is arranged in a boundary region with respect to an adjacent pixel and includes a material that reflects or absorbs light in order to suppress entering of light into the adjacent pixel. A representative example of the material of the light shielding member 16 is a metal material that reflects or absorbs light, and particularly is tungsten (W), aluminum (Al), silver (Ag), gold (Au), or the like.

Alternatively, the light shielding member 16 may include a material of a refractive index lower than that of the color filter region 14 or the photoelectric conversion region 13 (such material is hereinafter referred to as a low refractive index material). If the light shielding member 16 includes a low refractive index material, since light transmitted through the color filter region 14 or the photoelectric conversion region 13 and arriving at the surface of the light shielding member 16 is reflected by the surface, leakage of light to the adjacent pixel can be suppressed. A particular example of the low refractive index material is SiO₂ or an insulating material having a refractive index lower than that of SiO₂.

In the example of FIG. 5A, the light shielding member 16 including, for example, a metal material 18 is arranged at a pixel boundary portion in the photoelectric conversion region 13, and the light shielding member 16 including, for example, a low refractive index material is arranged at a pixel boundary portion in the color filter region 14. FIG. 5A depicts one example, and at pixel boundary portions in the photoelectric conversion region 13 and the color filter region 14, the light shielding members 16 including the same material (for example, the metal material 18 or the low refractive index material) may be arranged.

While the microstructure 11 in the dispersion region 12 can disperse light in one direction (X direction in FIG. 5A), it does not disperse the light in a direction intersecting the one direction (in FIG. 5B, in the Y direction) and transmits light of any wavelength therethrough without changing the direction of the incident light. Therefore, there is no necessity to arrange the light shielding member 16 in a boundary region between pixels adjacent to each other in the Y direction.

It is to be noted that the optical characteristic for dispersing light entering the microstructure 11 is changed by changing the material, width, length in the light propagation direction, or the like of the microstructure 11. Therefore, for example, the direction in which light in the red wavelength band is refracted and the direction in which light in the blue wavelength band is refracted from the microstructure 11 may possibly be reverse to those in FIG. 5A.

Further, although, in FIG. 4, the microstructure 11 is arranged above the green pixels G, the microstructure 11 may alternatively be arranged above the red pixels R and have such a dispersion characteristic that it transmits therethrough light in the red wavelength band as it is and refracts light in the green wavelength band and the blue wavelength band. In this case, it is sufficient if the light shielding member 16 is provided in a boundary region between a green pixel column and a blue pixel column. Similarly, the microstructure 11 may alternatively be arranged above the blue pixels B and have such a dispersion characteristic that it transmits therethrough light in the blue wavelength band as it is and refracts light in the red wavelength band and the green wavelength band. In this case, it is sufficient if the light shielding member 16 is provided in a boundary region between a red pixel column and a green pixel column.

In this manner, in the first embodiment, the dispersion region 12 is arranged on the light incidence face side of the photoelectric conversion region 13 such that incident light is dispersed in the dispersion region 12 to enter the photoelectric conversion region 13. The light shielding member 16 is arranged in a boundary region of pixels such that light dispersed in the dispersion region 12 may not enter an adjacent pixel beyond the boundary of pixels at the time of entering the photoelectric conversion region 13. Since the dispersion region 12 changes the propagation direction of light for each wavelength, a quantum efficiency Qe at the time when photoelectric conversion is performed by the photoelectric conversion region 13 can be enhanced. Further, by providing the light shielding member 16 on a pixel boundary across which there is the possibility that light dispersed in the dispersion region 12 may enter an adjacent pixel, color mixture can be prevented.

By providing the color filter region 14 between the photoelectric conversion region 13 and the dispersion region 12, the quantum efficiency Qe can be enhanced compared to an alternative case in which incident light is caused to directly enter the color filter region 14, and besides, by providing the light shielding member 16, color mixture can be prevented as well.

### Second Embodiment

The imaging device 1 according to a second embodiment is different from that according to the first embodiment in array of colors in pixels.

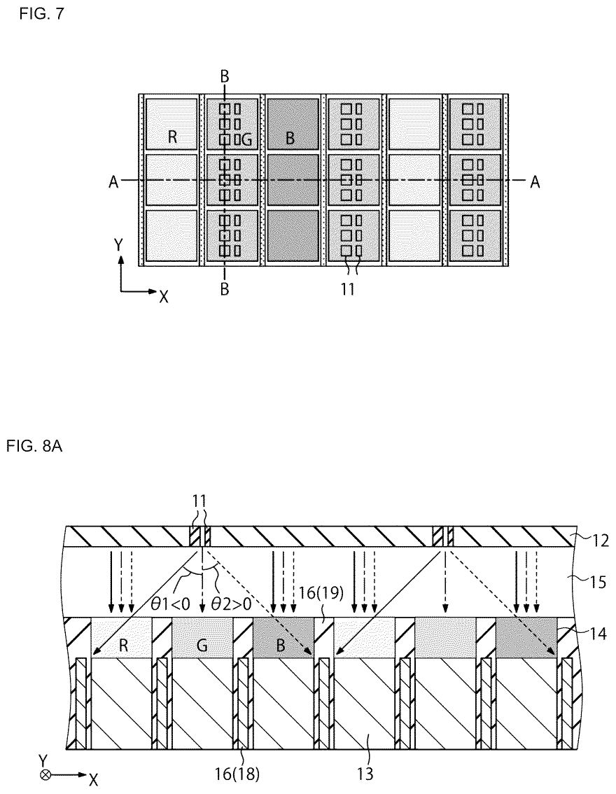

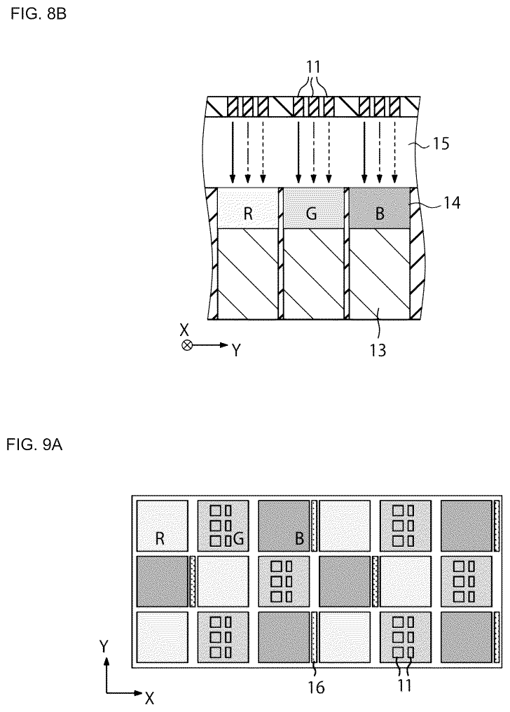

FIG. 7 is a top plan view of an essential part of the imaging device 1 according to the second embodiment, FIG. 8A is a cross sectional view taken along line A-A of FIG. 7, and FIG. 8B is a cross sectional view taken along line B-B of FIG. 7. Although, in FIG. 4, red, green, and blue pixels are arranged in order in the X direction, in FIG. 7, pixels of the respective colors are arranged symmetrically in the X direction with respect to a blue pixel column. In FIG. 7, six pixel columns arranged in the X direction are depicted. In the X direction, green pixel columns are arranged every other pixel.

Also in the imaging device 1 according to the second embodiment, the microstructure 11 is arranged above the green pixel columns. The dispersion characteristic of the microstructure 11 is the same as that of the microstructure 11 in the first embodiment. The microstructure 11 transmits therethrough light in the green wavelength band as it is and refracts light in the red wavelength band and light in the green wavelength band in directions opposite to each other in the X direction. It is to be noted that, since the microstructure 11 according to the second embodiment does not cause light to be dispersed in the Y direction as depicted in FIG. 8B, there is no necessity to provide the light shielding member 16 in a pixel boundary in the Y direction, as in the first embodiment.

In the photoelectric conversion region 13 and the color filter region 14 of FIG. 7, green pixel columns are arranged every other pixel in the X direction. Therefore, light refracted by the microstructure 11 advances in a direction toward boundary regions of all pixel columns. Therefore, it is necessary to arrange the light shielding member 16 in the boundary regions of all the pixel columns arranged in the X direction.

Also in the second embodiment, the dispersion characteristic of the microstructure 11 can be changed by adjusting the material, width, refractive index, or the like of the microstructure 11, and light in the red wavelength band and light in the blue wavelength band may not necessarily advance as in FIG. 8A. Further, the microstructure 11 may be arranged above the red pixels or the blue pixels. Above whichever color pixels the microstructure 11 is arranged, since, in the present embodiment, it is presupposed that the light shielding member 16 is arranged in the boundary regions of all the pixel columns in the X direction, entering of light into an adjacent pixel can be suppressed by similar arrangement of the light shielding member 16.

Although, in FIG. 8A, depicted is an example in which the color filter region 14 is provided between the photoelectric conversion region 13 and the dispersion region 12, the color filter region 14 is not necessarily an essential component, as in the first embodiment.

In this manner, in the second embodiment, in a case where green pixel columns are arranged every other pixel along the X direction, by providing the light shielding member 16 in each pixel boundary of a plurality of pixel columns arranged in the X direction, entering of light into a pixel adjacent in the X direction can be prevented, and color mixture can be suppressed.

### Third Embodiment

A third embodiment is different from the first and second embodiments in array of pixels of the respective colors. The position at which the light shielding member 16 is provided changes depending on the arrangement places of pixels of the respective colors.

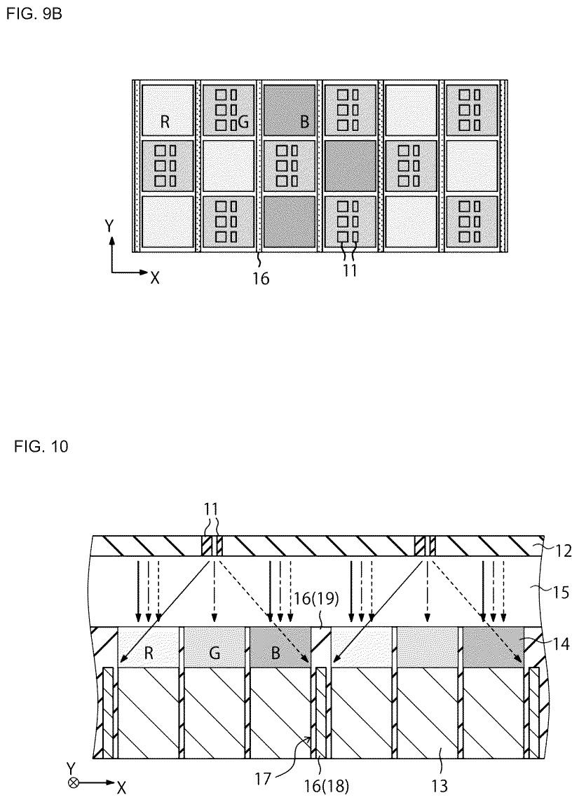

FIG. 9A is a top plan view of an essential part of the imaging device 1 according to the third embodiment. In FIG. 9A, pixels of the respective colors in the photoelectric conversion region 13 and the color filter region 14 are arranged in a staggered manner in terms of color. Further, in the example of FIG. 9A, the microstructure 11 is arranged above the green pixels as in the first and second embodiments. In a case where the dispersion characteristic of the microstructure 11 is the same as that in the first and second embodiments, the light shielding member 16 is provided on a pixel boundary between a red pixel and a blue pixel which are each adjacent to a green pixel in the X direction. Although, in the first and second embodiments, indicated is an example in which the light shielding member 16 of a length corresponding to a plurality of pixels in the Y direction is provided, in the third embodiment, the light shielding member 16 of a length corresponding to one pixel is provided.

FIG. 9B is a top plan view of an essential part of the imaging device 1 according to a modification of FIG. 9A. Although also pixels of the respective colors in FIG. 9B are arranged in a staggered manner in terms of color, the number of green pixels is greater than the number of pixels of the other colors. Also in the example of FIG. 9B, the microstructure 11 is arranged above the green pixels. Since the number of green pixels is greater than that in FIG. 9A, the number of rays of light that advance to the opposite sides in the X direction from the microstructure 11 increases. Therefore, it is necessary to provide the light shielding member 16 on a pixel boundary portion of all the pixel columns arranged in the X direction.

In this manner, in the third embodiment, since pixels of the respective colors are arranged in a staggered manner in terms of color, it is necessary to change the place at which the light shielding member 16 is arranged, depending on the number and the positions of the pixels above which the microstructure 11 is arranged.

### Fourth Embodiment

In a fourth embodiment, the material of the light shielding member 16 is described more specifically.

FIG. 10 is a cross sectional view of the imaging device 1 according to the fourth embodiment. In the fourth embodiment, indicated is an example in which the light shielding member 16 arranged in a boundary region of pixels which light dispersed by the microstructure 11 enters includes a metal material 18 and a low refractive index material 19.

In the fourth embodiment, for example, a trench 17 is formed in a boundary region of pixels, and the trench 17 is filled with the metal material 18 while the perimeter of the metal material 18 is covered with the low refractive index material 19, to thereby complete the light shielding member 16.

Although, in FIG. 10, the metal material 18 is arranged at the pixel boundary portion according to the height of the photoelectric conversion region 13, the metal material 18 may extend to the height of the color filter region 14.

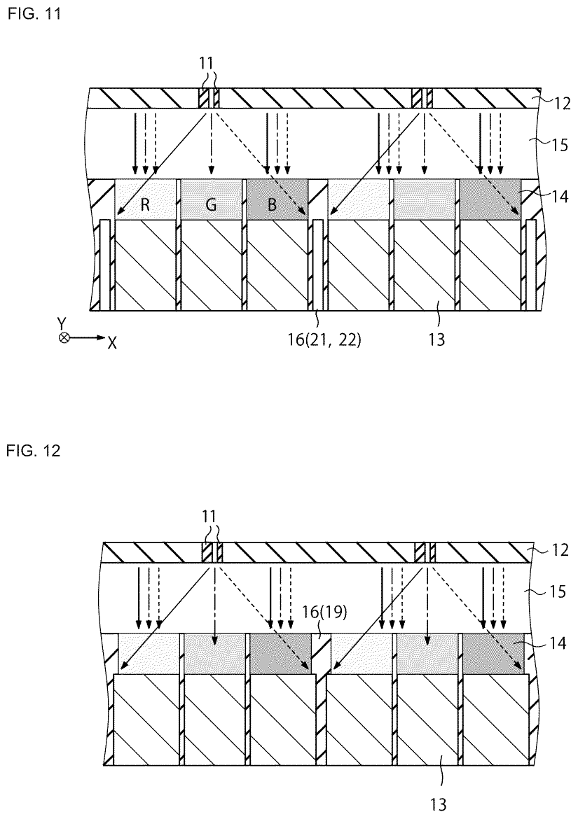

FIG. 11 is a cross sectional view of the imaging device 1 according to a first modification of FIG. 10. In FIG. 11, air is provided in place of the metal material 18 of FIG. 10. By forming the trench 17 at a pixel boundary portion and sealing the top of the trench 17 to form a cavity portion 21 without filling the inside of the trench 17, it is possible to fill the cavity portion 21 with air 22. Since the air 22 has a refractive index further lower than that of the low refractive index material 19 that includes an insulator or the like, light arriving at a wall face of the cavity portion 21 in contact with the air 22 is reflected at high efficiency by the wall face. Therefore, the possibility that light may be transmitted through the cavity portion 21 and enter an adjacent pixel can be eliminated.

It is to be noted that, although, in FIG. 11, the cavity portion 21 filled with the air 22 is provided at a pixel boundary portion according to the height of the photoelectric conversion region 13, the cavity portion 21 may be provided to extend to the height of the color filter region 14.

FIG. 12 is a cross sectional view of the imaging device 1 according to a second modification of FIG. 10. In FIG. 12, the width of the pixel boundary portion in contact with the color filter region 14 is increased compared to the width of the pixel boundary portion in contact with the photoelectric conversion region 13. At the pixel boundary portion, the light shielding member 16 including, for example, the low refractive index material 19 is provided. Since light dispersed by the microstructure 11 and entering the red color filter is oblique light, there is the possibility that the light may be transmitted through the red color filter and enter an adjacent pixel. Therefore, in FIG. 12, the width of the pixel boundary portion adjacent to the red color filter is increased, so that a greater quantity of the light shielding member 16 is arranged.

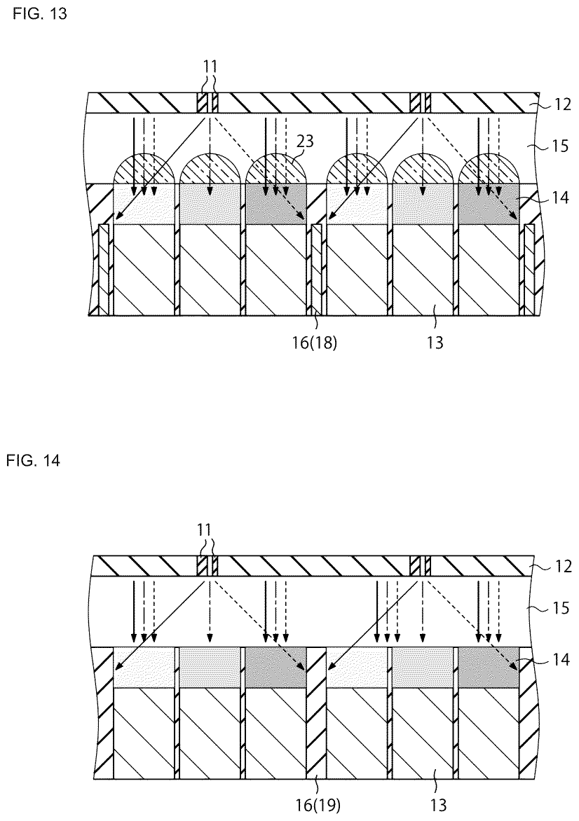

FIG. 13 is a cross sectional view of the imaging device 1 according to a third modification of FIG. 10. In the imaging device 1 of FIG. 13, an on-chip lens array 23 is arranged on the light incidence face side of the color filter region 14, and the dispersion region 12 is arranged on the light incidence face side of the on-chip lens array 23. The on-chip lens array 23 has a refractive index higher than the refractive index of the light transmission region 15 in contact with the on-chip lens array 23. Therefore, light entering the on-chip lens array 23 in a direction inclined with respect to an optical axis is refracted by the on-chip lens array 23 and advances in a direction closer to the optical axis.

Therefore, light in the red wavelength band and light in the blue wavelength band dispersed in the dispersion region 12 and advancing in oblique directions enter the on-chip lens array 23 and are refracted in directions closer to a direction normal to the light incidence face. Consequently, the amount of light that enters a boundary region of pixels can be reduced, and color mixture can be suppressed.

FIG. 14 is a cross sectional view of the imaging device 1 according to a fourth modification of FIG. 10. In FIG. 14, the width of the pixel boundary region which there is the possibility that oblique light dispersed by the microstructure 11 may enter, from among the pixel boundary portions in the photoelectric conversion region 13 and the color filter region 14, is increased, so that a greater quantity of the light shielding member 16 is arranged. Although, in the example of FIG. 14, depicted is an example in which the light shielding member 16 includes the low refractive index material 19, the metal material 18 or the air 22 may be arranged at least partially. In the present specification, the light shielding member 16 arranged along a pixel boundary portion in the color filter region 14 is referred to as a first light shielding portion, and the light shielding member 16 arranged along a pixel boundary portion in the photoelectric conversion region 13 is referred to as a second light shielding portion. While, in FIG. 12, the width of the first light shielding portion is made greater than the width of the second light shielding portion, in FIGS. 13 and 14, the widths of the first light shielding portion and the second light shielding portion are made equal to each other. Further, while the second light shielding portion in FIG. 13 has the light shielding member 16 including the metal material 18, the second light shielding portion in FIG. 14 does not have the light shielding member 16 including the metal material 18. Further, in FIGS. 12 to 14, the interval of a pixel boundary portion in the color filter region 14 at which the first light shielding portion is arranged is made greater than the interval of a pixel boundary portion of pixels which a chief ray enters.

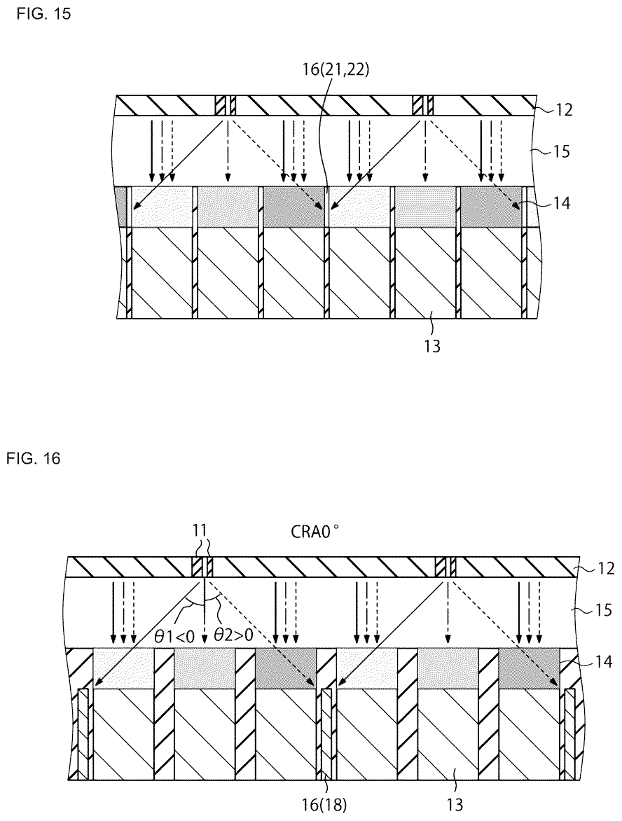

FIG. 15 is a cross sectional view of the imaging device 1 according to a fifth modification of FIG. 10. In the imaging device 1 of FIG. 15, the cavity portion 21 filled with the air 22 is provided at the pixel boundary portion which there is the possibility that oblique light dispersed by the microstructure 11 may enter, from among the pixel boundary portions in the color filter region 14. Since the air 22 is lower in refractive index than the other low refractive index material 19, oblique light from the microstructure 11 can be reflected at high efficiency. Although, in the imaging device 1 of FIG. 15, the cavity portion 21 is provided at a pixel boundary portion in the color filter region 14, it may otherwise be provided at a pixel boundary portion in the photoelectric conversion region 13.

It is to be noted that the cavity portion 21 in FIG. 15 may be extended in a depthwise direction to the photoelectric conversion region 13. Further, although, in FIG. 15, the width of the pixel boundary portion which there is the possibility that oblique light from the microstructure 11 may enter is made substantially equal to the width of the other pixel boundary portions, the width of the pixel boundary portions in which the light shielding member 16 is provided may be increased as in FIGS. 12 to 14.

In this manner, in the fourth embodiment, since the shape or the material of the pixel boundary portion which there is the possibility that oblique light dispersed by the microstructure 11 may enter is made different from that of the other pixel boundary portions to form the light shielding member 16, it is possible to suppress entering of oblique light dispersed by the microstructure 11 into an adjacent pixel.

### Fifth Embodiment

In a fifth embodiment, pupil correction is performed.

Although, in the imaging device 1 according to the first to fourth embodiments, ideally it is desirable that light enter from the direction normal to the light incidence face, practically light sometimes enters from a direction inclined with respect to the normal direction. Therefore, the positions of the color filters and the microstructures 11 are slightly displaced with respect to the pixel positions in the photoelectric conversion region 13 to perform pupil correction such that, even if light enters from a direction inclined with respect to the direction normal to the light incidence face, imaging can be performed correctly.

FIG. 16 is a view depicting an example in which light enters from the direction normal to the light incidence face. FIG. 16 depicts an example in which the chief ray angle (CRA) is 0°. In the case where the chief ray angle is 0°, it is necessary for the pixel positions in the photoelectric conversion region 13, the pixel positions in the color filter region 14, and the pixel positions at which the microstructure 11 is arranged in the dispersion region 12 to coincide with one another.

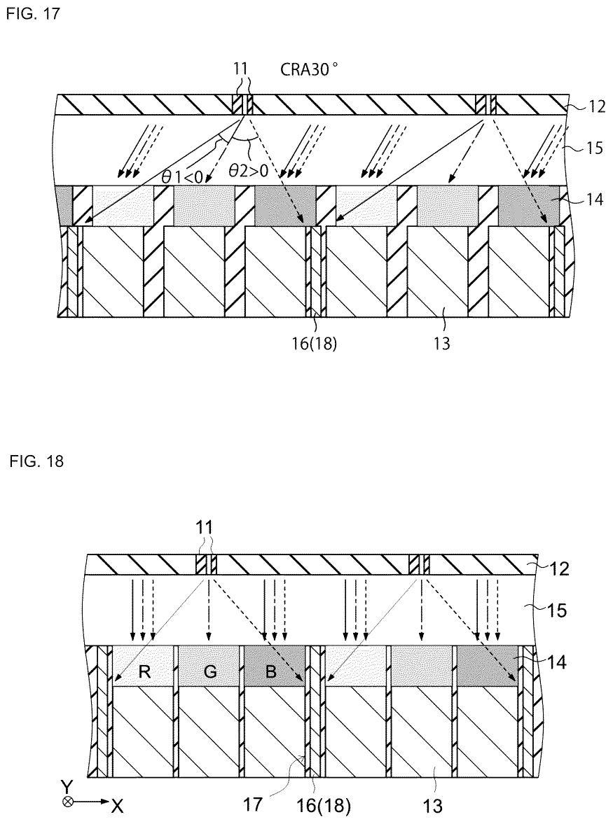

FIG. 17 is a view depicting an example in which light enters from a direction inclined with respect to the direction normal to the light incidence face. FIG. 17 depicts an example in which the chief ray angle is 30°. In the case where the chief ray angle is deviated from 0°, preferably, the pixel positions in the color filter region 14 and the positions of the microstructures 11 in the dispersion region 12 are displaced with respect to the pixel positions in the photoelectric conversion region 13, according to the chief ray angle.

When the imaging device 1 is to be designed, the positional relation of the photoelectric conversion region 13, the color filter region 14, and the dispersion region 12 is adjusted such that light from within an allowable range for the chief ray angle can be imaged.

As depicted in FIG. 17, in the case where the chief ray angle is not 0°, light in the wavelength band of green that is a chief ray transmitted through the microstructure 11 advances in a direction inclined with respect to the direction normal to the light incidence face. In FIG. 17, the inclination angle of light in the wavelength band of green is θ0. In this case, light in the wavelength band of red dispersed by the microstructure 11 advances with an inclination angle θ1, and light in the wavelength band of blue dispersed by the microstructure 11 advances with an inclination angle θ2.

In comparison with the case in which the chief configuration angle is 0° in FIG. 16, although the inclination angle θ1 of light in the wavelength band of red in FIG. 17 is greater than the inclination angle θ1 in FIG. 16 and the inclination angle θ2 of light in the wavelength band of blue in FIG. 17 is smaller than the inclination angle θ2 in FIG. 16, it is common that light in the wavelength band of red enters the red color filter and light in the wavelength band of blue enters the blue color filter.

Therefore, even if the chief ray angle is different from 0°, it is sufficient if the light shielding member 16 is arranged in the boundary region of pixels which light refracted and advancing in a direction other than that of the chief ray enters.

In this manner, in the fifth embodiment, even if the chief ray angle of light entering the imaging device 1 is different from 0°, color mixture can be prevented by providing the light shielding member 16 in the boundary region of pixels which light dispersed by the microstructure 11 and advancing with an angle other than the chief ray angle enters.

### Sixth Embodiment

The imaging device 1 according to a sixth embodiment achieves further suppression of color mixture than the imaging device 1 according to the first to fourth embodiments.

FIG. 18 is a cross sectional view of the imaging device 1 according to the sixth embodiment. In FIG. 18, components common to those in FIG. 8A are denoted by the same reference signs, and the following description is given focusing on differences. The imaging device 1 of FIG. 18 includes the light shielding member 16 including the metal material 18 arranged at the pixel boundary portion in the photoelectric conversion region 13 and at the pixel boundary portion in the color filter region 14. More specifically, the light shielding member 16 is arranged in such a manner as to extend along the depthwise direction of the pixel boundary portion from an end face of the photoelectric conversion region 13 on the side opposite to the light incidence face to the light incidence face side of the color filter region 14.

Consequently, even if light dispersed by the microstructure 11 enters the color filter region 14, the light having been transmitted through the color filter region 14 can be reflected or absorbed by the light shielding member 16. Therefore, such a situation that light entering the color filter region 14 obliquely and transmitted through the color filter region 14 enters the photoelectric conversion region 13 of an adjacent pixel can be prevented, and color mixture can be suppressed.

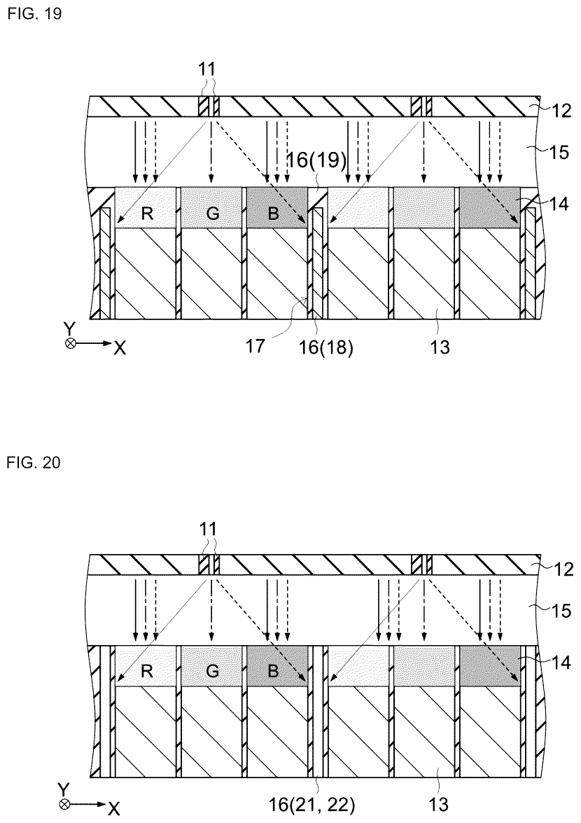

FIG. 19 is a cross sectional view of the imaging device 1 according to a first modification of FIG. 18. Although, in the imaging device 1 in FIG. 18, the light shielding member 16 is arranged in such a manner that it extends through the pixel boundary portion in the photoelectric conversion region 13 and the color filter region 14, the light shielding member 16 including the metal material 18 in the imaging device 1 in FIG. 19 extends through the pixel boundary portion in the photoelectric conversion region 13 to such a depth that it does not extend through the pixel boundary portion of the color filter region 14. The perimeter of the metal material 18 in the pixel boundary portion is covered with the low refractive index material 19.

In the case of the imaging device 1 in FIG. 19, there is the possibility that light dispersed by the microstructure 11 may enter an adjacent pixel while passing through a portion at which the light shielding member 16 is not arranged. However, by devising the structure of the microstructure 11, the rate of light entering an adjacent pixel can be suppressed to the minimum. Further, in a case where a trench is formed at the pixel boundary portion from a lower face side in FIG. 19 and the light shielding member 16 is embedded in the trench, for the convenience of the manufacturing process, it is sometimes difficult to form such a trench that it extends through the pixel boundary portion in the color filter region 14, and therefore, also the imaging device 1 of the structure in FIG. 19 is useful.

### Seventh Embodiment

FIG. 20 is a cross sectional view of the imaging device 1 according to a seventh embodiment. In the imaging device 1 in FIG. 20, components common to those of the imaging device 1 in FIG. 11 are denoted by the same reference signs, and in the following, description is given focusing on differences. In the imaging device 1 in FIG. 20, the cavity portion 21 arranged at the pixel boundary portion is arranged in such a manner as to extend from an end face of the photoelectric conversion region 13 on the side opposite to the light incidence face to the light incidence face of the color filter region 14. That is, although, in the imaging device 1 in FIG. 11, the cavity portion 21 is not arranged at the pixel boundary portion in the color filter region 14, in the imaging device 1 in FIG. 20, the cavity portion 21 is arranged also at the pixel boundary portion in the color filter region 14.

In the imaging device 1 in FIG. 20, in a case where light dispersed by the microstructure 11 is transmitted through the color filter region 14 and arrives at the pixel boundary portion, it can be reflected by the cavity portion 21. If the light shielding member 16 is provided as depicted in FIG. 18 or 19 in place of the cavity portion 21, the light shielding member 16 not only reflects light but also absorbs light, and therefore, the quantum efficiency of the photoelectric conversion region 13 drops. In contrast, since the cavity portion 21 does not absorb light and reflects light with certainty, the quantum efficiency can be improved.

Although, in FIG. 20, the cavity portion 21 is arranged in such a manner as to extend through the pixel boundary portion in the color filter region 14, the cavity portion 21 may be arranged in such a manner as to extend to such a depth that it does not extend through the pixel boundary portion in the color filter region 14.

In this manner, in the seventh embodiment, since the cavity portion 21 is provided at the pixel boundary portion in the photoelectric conversion region 13 and the color filter region 14, when light dispersed by the microstructure 11 is transmitted through the color filter region 14 and enters the cavity portion 21, it can be reflected efficiently by the cavity portion 21, and the quantum efficiency can be improved.

### Eighth Embodiment

An eighth embodiment is characterized in that the microstructure is provided not only on the light incidence face side but also on the side opposite to the light incidence face side.

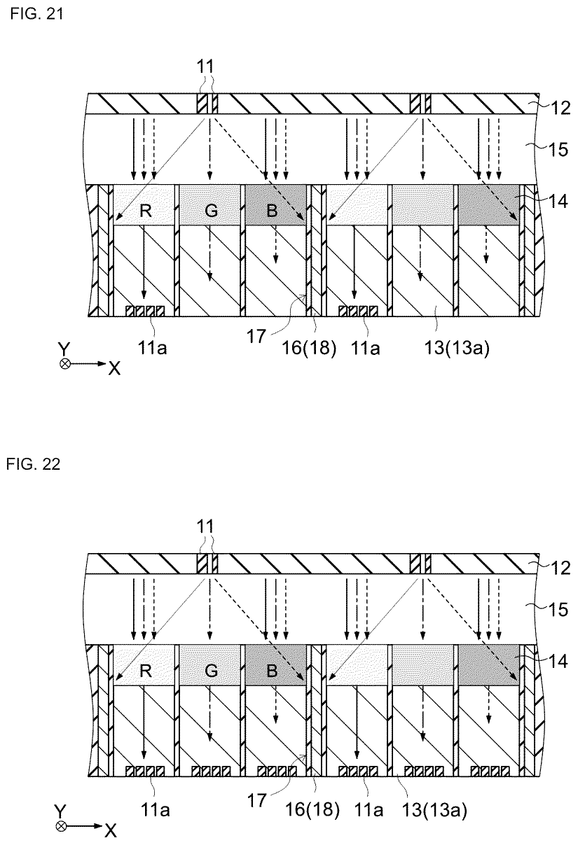

FIG. 21 is a cross sectional view of the imaging device 1 according to the eighth embodiment. In the imaging device 1 in FIG. 21, components common to those of the imaging device 1 in FIG. 18 are denoted by the same reference signs, and in the following, description is given focusing on differences. The imaging device 1 in FIG. 21 includes, in addition to the cross sectional structure of the imaging device 1 in FIG. 18, a microstructure 11a arranged along a face of some of the photoelectric conversion portions 13a in the photoelectric conversion region 13 on the side opposite to the light incidence face. In the example in FIG. 21, the microstructure (second microstructure) 11a is arranged along the face of the photoelectric conversion portion 13a on which the color filter region 14 of red is arranged, on the side opposite to the light incidence face.

Although light transmitted through the color filter region 14 of red is photoelectrically converted by the photoelectric conversion portion 13a, part of the light is transmitted through the photoelectric conversion portion 13a and enters and is diffused by the microstructure 11a. Since the diffused light is photoelectrically converted by the photoelectric conversion portion 13a, the quantum efficiency can be improved.

Although, in FIG. 21, the microstructure 11a is arranged only at the photoelectric conversion portion 13a corresponding to the color filter region 14 of red, the microstructure 11a may be arranged also at the photoelectric conversion portion 13a corresponding to the color filter region 14 of the other colors.

FIG. 22 is a cross sectional view of the imaging device 1 according to a modification of FIG. 21. In the imaging device 1 in FIG. 22, the microstructure 11a is arranged at the photoelectric conversion portions 13a corresponding to all the colors on the side opposite to the light incidence face. The microstructures 11a may have a periodic structure of the same shape or may have periodic structures of shapes different among different colors. The diffraction efficiency differs for each wavelength and changes substantially in proportion to the wavelength. More specifically, preferably, as the wavelength of light increases, the period of the microstructure 11a is made longer. For example, in a case where there are four photoelectric conversion portions 13a corresponding to four color filter regions 14 of red, green, blue, and infrared, preferably, the period of the periodic structure of the microstructures 11a on the side opposite to the light incidence face is set so as to decrease in the order of infrared>red>green>blue. Although light having a great wavelength undergoes diffraction by the microstructure 11a having a long period, since it does not undergo diffraction by the microstructure 11a having a short period, by changing the period of the microstructure 11a according to the wavelength, light having entered each photoelectric conversion portion 13a can be confined inside the photoelectric conversion portion 13a, and the quantum efficiency can be improved.

In this manner, in the eighth embodiment, by providing the microstructure 11a along the face of at least some of the photoelectric conversion portions 13a on the side opposite to the light incidence face, it is possible to diffuse light that has transmitted through the photoelectric conversion portion 13a and that has entered the microstructure 11a, with use of the microstructure 11a, to thereby increase the optical path length, so that the quantum efficiency can be improved.

### <Application Example to Mobile Body>

The technology according to the present disclosure (present technology) can be applied to various products. For example, the technology according to the present disclosure may be implemented as a device incorporated in any of various kinds of mobile bodies such as automobiles, electric automobiles, hybrid electric automobiles, motorcycles, bicycles, personal mobilities, airplanes, drones, ships, and robots.

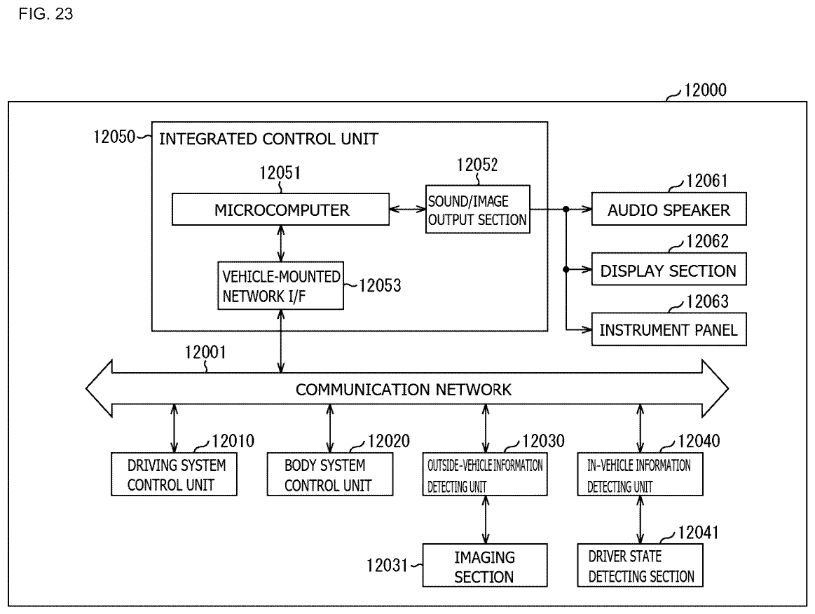

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

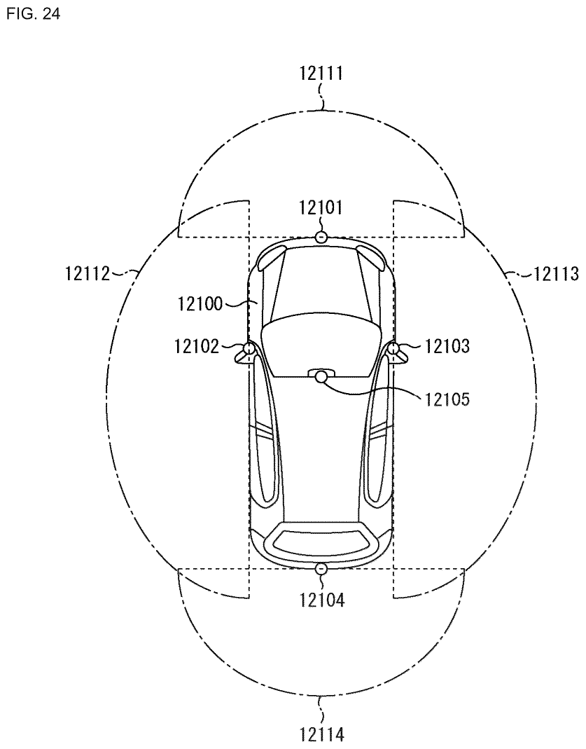

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of a vehicle control system to which the technology according to the present disclosure can be applied has been described. The technology according to the present disclosure can be applied to the imaging section 12031 and so forth from among the configurations described hereinabove. In particular, the imaging device 1 of the present disclosure can be applied to the imaging section 12031. By applying the technology according to the present disclosure to the imaging section 12031, a clearer captured image can be obtained, and therefore, the fatigue of the driver can be reduced.

It is to be noted that the present technology can adopt the following configurations.

(1)

An imaging device including:
a photoelectric conversion region including a photoelectric conversion portion for each of pixels;
a dispersion region that is arranged on a side nearer to a light incidence face than the photoelectric conversion region and that causes incident light to be dispersed according to a wavelength; and
a light shielding member arranged along a boundary of pixels which light dispersed in an angle different from a chief ray angle in the dispersion region enters.
   (2)

The imaging device according to (1), in which
the light shielding member causes light transmitted through a corresponding pixel to be reflected or absorbed.
   (3)

The imaging device according to (1) or (2), in which
the light shielding member extends in a depthwise direction of the photoelectric conversion region along the boundary of the pixels.
   (4)

The imaging device according to any one of (1) to (3), in which
the light shielding member includes a conductive material that causes incident light to be reflected or absorbed.
   (5)

The imaging device according to any one of (1) to (3), in which
the light shielding member includes a material having a refractive index lower than that of the photoelectric conversion region.
   (6)

The imaging device according to any one of (1) to (3), in which
the light shielding member has a cavity portion filled with air.
   (7)

The imaging device according to any one of (1) to (6), in which
the dispersion region causes the light dispersed in a direction according to the wavelength of the incident light to enter a pixel of a corresponding color in the photoelectric conversion region.
   (8)

The imaging device according to (7), in which
a plurality of pixels are arranged in order for each color along one direction in the photoelectric conversion region,
the dispersion region causes the light dispersed in a direction according to the wavelength of the incident light to enter at least some of the plurality of pixels arranged in the one direction in the photoelectric conversion region, and
the light shielding member is arranged along a boundary of pixels which the light dispersed in the dispersion region enters.
   (9)

The imaging device according to (8), in which
the light shielding member is arranged only on a boundary of some of the plurality of pixels arranged in the one direction in the photoelectric conversion region.
   (10)

The imaging device according to (8), in which
the light shielding member is arranged on the boundary of all of the plurality of pixels arranged in the one direction in the photoelectric conversion region.
   (11)

The imaging device according to any one of (1) to (10), including:
a color filter region that is arranged between the photoelectric conversion region and the dispersion region and that includes color filters corresponding to the pixels.
   (12)

The imaging device according to (11), in which
the light shielding member is arranged at at least one of a pixel boundary portion in the color filter region or a pixel boundary portion in the photoelectric conversion region.
   (13)

The imaging device according to (12), in which
the light shielding member is arranged to extend from the pixel boundary portion in the photoelectric conversion region to the pixel boundary portion in the color filter region.
   (14)

The imaging device according to any one of (11) to (13), in which
the light shielding member includes
   a first light shielding portion arranged along a pixel boundary in the color filter region, and
   a second light shielding portion that is arranged along a pixel boundary in the photoelectric conversion region and that includes a material different from that of the first light shielding portion.
      (15)

The imaging device according to (14), in which
the first light shielding portion includes a material that causes the incident light to be reflected, and
the second light shielding portion includes a conductive material that causes the incident light to be reflected or absorbed.
   (16)

The imaging device according to (14) or (15), in which
at least one of the first light shielding portion or the second light shielding portion has a cavity portion filled with air.
   (17)

The imaging device according to any one of (14) to (16), in which
an interval of a pixel boundary portion in the color filter region at a location at which the first light shielding portion is arranged is greater than an interval of a pixel boundary portion of pixels which a chief ray enters.
   (18)

The imaging device according to any one of (1) to (17), in which
the dispersion region includes a first microstructure that causes the incident light to be dispersed in one direction according to the wavelength and that allows the incident light to advance straightforwardly in a direction intersecting the one direction, and
the light shielding member is arranged along a boundary of at least some of the pixels in the one direction.
   (19)

The imaging device according to (18), in which
the first microstructure transmits therethrough light in a specific wavelength band and causes light in any wavelength band other than the specific wavelength band to be dispersed in the one direction, and
the light shielding member is arranged along a boundary of pixels corresponding to the wavelength bands other than the specific wavelength band in the one direction.
   (20)

The imaging device according to (18) or (19), including:
a plurality of the first microstructures arranged along a direction intersecting the one direction.
   (21)

The imaging device according to any one of (18) to (20), including:
a second microstructure that is arranged along a face of the photoelectric conversion portion on a side opposite to the light incidence face and that diffuses light transmitted through the photoelectric conversion portion.
   (22)

The imaging device according to (21), in which
the second microstructure is provided for each of all of the photoelectric conversion portions or is provided for some of the photoelectric conversion portions that perform photoelectric conversion for light having a specific wavelength.
   (23)

Electronic equipment including:
an imaging device that outputs a pixel signal obtained by imaging; and
a signal processing section that performs signal processing for the pixel signal, in which
the imaging device includes
   a photoelectric conversion region including a photoelectric conversion portion for each of pixels,
   a dispersion region that is arranged on a side nearer to a light incidence face than the photoelectric conversion region and that causes incident light to be dispersed according to a wavelength, and
   a light shielding member arranged along a boundary of pixels which light dispersed in an angle different from a chief ray angle in the dispersion region enters.

The mode of the present disclosure is not restricted to the individual embodiments described hereinabove and includes various modifications that those skilled in the art can come up with, and also the advantageous effects of the present disclosure are not restricted to the substance described hereinabove. That is, it is possible to make various additions, alterations, and partial deletions without departing from the conceptual ideas and scopes of the present disclosure derived from the substance defined in the claims and equivalents to them.

### REFERENCE SIGNS LIST

1: Imaging device
2: Pixel array section
3: Vertical driving circuit
4: Column signal processing circuit
5: Horizontal driving circuit
6: Outputting circuit
7: Control circuit
10: Pixel
11: Microstructure
12: Dispersion region
13: Photoelectric conversion region
14: Color filter region
15: Light transmission region
16: Light shielding member
17: Trench
18: Metal material
19: Low refractive index material
21: Cavity portion
22: Air
23: On-chip lens array

1. An imaging device comprising:
a photoelectric conversion region including a photoelectric conversion portion for each of pixels;
a dispersion region that is arranged on a side nearer to a light incidence face than the photoelectric conversion region and that causes incident light to be dispersed according to a wavelength; and
a light shielding member arranged along a boundary of pixels which light dispersed in an angle different from a chief ray angle in the dispersion region enters.

2. The imaging device according to claim 1, wherein
the light shielding member causes light transmitted through a corresponding pixel to be reflected or absorbed.

3. The imaging device according to claim 1, wherein
the light shielding member extends in a depthwise direction of the photoelectric conversion region along the boundary of the pixels.

4. The imaging device according to claim 1, wherein
the light shielding member includes a conductive material that causes incident light to be reflected or absorbed.

5. The imaging device according to claim 1, wherein
the light shielding member includes a material having a refractive index lower than that of the photoelectric conversion region.

6. The imaging device according to claim 1, wherein
the light shielding member has a cavity portion filled with air.

7. The imaging device according to claim 1, wherein
the dispersion region causes the light dispersed in a direction according to the wavelength of the incident light to enter a pixel of a corresponding color in the photoelectric conversion region.

8. The imaging device according to claim 7, wherein
a plurality of pixels are arranged in order for each color along one direction in the photoelectric conversion region,
the dispersion region causes the light dispersed in a direction according to the wavelength of the incident light to enter at least some of the plurality of pixels arranged in the one direction in the photoelectric conversion region, and
the light shielding member is arranged along a boundary of pixels which the light dispersed in the dispersion region enters.

9. The imaging device according to claim 8, wherein
the light shielding member is arranged only on a boundary of some of the plurality of pixels arranged in the one direction in the photoelectric conversion region.

10. The imaging device according to claim 8, wherein
the light shielding member is arranged on the boundary of all of the plurality of pixels arranged in the one direction in the photoelectric conversion region.

11. The imaging device according to claim 1, comprising:
a color filter region that is arranged between the photoelectric conversion region and the dispersion region and that includes color filters corresponding to the pixels.

12. The imaging device according to claim 11, wherein
the light shielding member is arranged at at least one of a pixel boundary portion in the color filter region or a pixel boundary portion in the photoelectric conversion region.

13. The imaging device according to claim 12, wherein
the light shielding member is arranged to extend from the pixel boundary portion in the photoelectric conversion region to the pixel boundary portion in the color filter region.

14. The imaging device according to claim 11, wherein
the light shielding member includes
a first light shielding portion arranged along a pixel boundary in the color filter region, and
a second light shielding portion that is arranged along a pixel boundary in the photoelectric conversion region and that includes a material different from that of the first light shielding portion.

15. The imaging device according to claim 14, wherein
the first light shielding portion includes a material that causes the incident light to be reflected, and
the second light shielding portion includes a conductive material that causes the incident light to be reflected or absorbed.

16. The imaging device according to claim 14, wherein
at least one of the first light shielding portion or the second light shielding portion has a cavity portion filled with air.

17. The imaging device according to claim 14, wherein
an interval of a pixel boundary portion in the color filter region at a location at which the first light shielding portion is arranged is greater than an interval of a pixel boundary portion of pixels which a chief ray enters.

18. The imaging device according to claim 1, wherein
the dispersion region includes a first microstructure that causes the incident light to be dispersed in one direction according to the wavelength and that allows the incident light to advance straightforwardly in a direction intersecting the one direction, and
the light shielding member is arranged along a boundary of at least some of the pixels in the one direction.

19. The imaging device according to claim 18, wherein
the first microstructure transmits therethrough light in a specific wavelength band and causes light in any wavelength band other than the specific wavelength band to be dispersed in the one direction, and
the light shielding member is arranged along a boundary of pixels corresponding to the wavelength bands other than the specific wavelength band in the one direction.

20. The imaging device according to claim 18, comprising:
a plurality of the first microstructures arranged along a direction intersecting the one direction.

21. The imaging device according to claim 18, comprising:
a second microstructure that is arranged along a face of the photoelectric conversion portion on a side opposite to the light incidence face and that diffuses light transmitted through the photoelectric conversion portion.

22. The imaging device according to claim 21, wherein
the second microstructure is provided for each of all of the photoelectric conversion portions or is provided for some of the photoelectric conversion portions that perform photoelectric conversion for light having a specific wavelength.

23. Electronic equipment comprising:
an imaging device that outputs a pixel signal obtained by imaging; and
a signal processing section that performs signal processing for the pixel signal, wherein
the imaging device includes
a photoelectric conversion region including a photoelectric conversion portion for each of pixels,
a dispersion region that is arranged on a side nearer to a light incidence face than the photoelectric conversion region and that causes incident light to be dispersed according to a wavelength, and
a light shielding member arranged along a boundary of pixels which light dispersed in an angle different from a chief ray angle in the dispersion region enters.
